(19) United States
(12) Patent Application Publication
(10) Pub. No.: US 2010/0110796 A1
(43) Pub. Date: May 6, 2010

(54) METHOD OF PERFORMING ERASE OPERATION IN NON-VOLATILE MEMORY DEVICE

(75) Inventors: Jong-Yeol Park, Goyang-si (KR); Jin-Yub Lee, Seoul (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: Samsung Electronics Co., Ltd., Suwon-si (KR)

(21) Appl. No.: 12/609,127

(22) Filed: Oct. 30, 2009

(30) Foreign Application Priority Data
Nov. 4, 2008 (KR) 20080108804

(51) Int. Cl. G11C 16/04; G11C 16/16

(52) U.S. Cl. 365/185.19; 365/185.29; 365/185.22

(57) ABSTRACT

A method of performing an erase operation in a non-volatile memory device includes a multi-erase operation and a post-erase operation. The multi-erase operation includes multi-erasing multiple memory blocks at the same time using a multi-erase voltage. The post-erase operation includes post-erasing one or more failed memory blocks of the multi-erased memory blocks using a post-erase voltage having sequentially increasing voltage values based on incremental step pulses (ISPs).

### CROSS-REFERENCE TO RELATED APPLICATIONS

A claim of priority is made to Korean Patent Application No. 2008-0108804, filed on Nov. 4, 2008 in the Korean Intellectual Property Office (KIPO), the subject matter of which is hereby incorporated by reference.

### BACKGROUND

Various embodiments relate to a non-volatile memory device, and more particularly to a method of performing erase operations in non-volatile memory devices.

Semiconductor memory devices may be volatile memory devices or non-volatile memory devices, according to whether stored information is retained when power to the devices is off. Non-volatile memory devices may include electrically erasable and programmable random access memory (EEPROM) devices, which are electrically erasable and programmable.

Operations of an EEPROM include a program mode in which data is written into memory cells, a read mode in which the written or stored data is read from the memory cells, and an erase mode in which the stored data is erased to initialize the memory cells. In an incremental step pulse program (ISPP) method, a verification operation and a re-programming operation after the verification operation are repeated by sequentially increasing a program voltage using multiple pulses.

In flash memory devices pertaining to EEPROM, erase operations may be simultaneously performed with respect to each block or sector, and program operations may be performed with respect to each page including multiple memory cells coupled to a common word line. Based on memory cell array structure, flash memory devices may be divided into NAND flash memory devices, in which cell transistors are serially coupled between a bit line and a ground voltage, and NOR flash memory devices, in which cell transistors are arranged in parallel between a bit line and a ground voltage. The NOR flash memory devices generally have an advantage of bitwise access in a read operation and a program operation, whereas the NAND flash memory devices have relatively higher speeds in program and erase operations.

As semiconductor memory devices become more highly integrated, the corresponding memory capacity of the semiconductor memory devices increases. Increases in memory capacity, according to development of various semiconductor techniques, correlates to an increase of the number of memory cells included in one chip. When the number of total memory cells increases, the number of failed memory cells may also increase. Because the read, erase and program operations are independently performed in non-volatile memory devices, time required for erasing the memory blocks may determine not only performance of the non-volatile memory device, but also overall performance of the system including the non-volatile memory device. As the number of failed memory blocks or sectors increases, the erasing time increases, and thus the performance of the non-volatile memory device deteriorates.

### SUMMARY

Exemplary embodiments provide methods of erasing a non-volatile memory device, for example, which reduce erase time and degradation of memory cells caused by over-erasing. Also, exemplary embodiments provide a non-volatile memory device and a system including the same for reducing erase time and degradation of the memory cells.

In various exemplary embodiments, a method of performing an erase operation in a non-volatile memory device includes a multi-erase operation and a post-erase operation. The multi-erase operation includes multi-erasing multiple memory blocks at the same time using a multi-erase voltage. The post-erase operation includes post-erasing one or more failed memory blocks of the multi-erased memory blocks using a post-erase voltage having sequentially increasing voltage values based on incremental step pulses (ISPs).

In various embodiments, a minimum post-erase voltage value corresponding to a start pulse of the ISP may be higher than the multi-erase voltage.

In various embodiments, the method of performing the erase operation in the non-volatile memory device may further include identifying a memory block as a defective memory block when the memory block remains failed after erasing the memory block using a maximum post-erase voltage value corresponding to a last pulse of the ISPs.

In various embodiments, the method of performing an erase operation may further include providing fail information of the failed memory blocks to an external memory control device; and receiving instructions and block addresses from the memory control device, the post-erasing being performed based on the received instructions and block addresses.

In various embodiments, the method of performing an erase operation may further include storing fail information regarding the failed memory blocks after the multi-erasing within the non-volatile memory device. The post-erasing may then be performed based on the stored fail information.

The post-erasing may include selecting one memory block of the failed memory blocks and erasing the selected memory block using the incrementally increasing post-erase voltage based on the ISPs. Selecting one memory block and erasing the selected memory block may be repeated with respect to each of the failed memory blocks.

Alternatively, the post-erasing may include selecting all of the failed memory blocks after the multi-erasing, simultaneously erasing all of the selected failed memory blocks using the post-erase voltage; identifying a passed memory block based on an erase verification; and de-selecting the passed memory block from the selected failed memory blocks. Simultaneously erasing the selected failed memory blocks and de-selecting a passed memory block may be repeated using the incrementally increasing post-erase voltage based on the ISPs.

The selecting all of the failed memory blocks and the de-selecting the passed memory block may be performed based on fail information stored in a status register included in the non-volatile memory device.

The multi-erasing may include receiving a block selection instruction and an address of the memory block to be erased from an external memory control device; storing erase information in a block decoder included in the non-volatile memory device based on the received address; and repeating the receiving and the storing until all of the memory blocks to be erased are selected. The multi-erase voltage is applied to the memory blocks at the same time.

The multi-erase voltage and the post-erase voltages based on the ISPs may correspond to a bulk voltage applied to a substrate or a well region, in which flash memory cells are formed.

### BRIEF DESCRIPTION OF THE DRAWINGS

Exemplary embodiments of the inventive concept will be described with reference to the attached drawings.

FIG. 1 is a flow chart illustrating a method for performing an erase operation in a non-volatile memory device, according to exemplary embodiments.

FIG. 2 is a diagram illustrating a multi-erase voltage and an incrementally increasing post-erase voltage based on ISPs, according to exemplary embodiments.

FIG. 3 is a flow chart illustrating an example of a multi-erase operation, according to exemplary embodiments.

FIG. 4 is a flow chart illustrating a post-erase operation, according to exemplary embodiments.

FIG. 5 is a block diagram illustrating a non-volatile memory device, according to exemplary embodiments.

FIG. 6 is a block diagram illustrating an example configuration for selecting memory blocks of the non-volatile memory device of FIG. 5, according to exemplary embodiments.

FIG. 7 is a block diagram illustrating an example of a block decoder circuit included in the non-volatile memory device of FIG. 6, according to exemplary embodiments.

FIG. 8 is a diagram illustrating signals for controlling the block decoder circuit of FIG. 7, according to exemplary embodiments.

FIG. 9 is a cross-sectional view of a non-volatile memory cell, according to exemplary embodiments.

FIG. 10 is a flowchart illustrating a post-erase operation, according to exemplary embodiments.

FIG. 11 is a diagram illustrating an example of a status register included in the non-volatile memory device of FIG. 5, according to exemplary embodiments.

FIG. 12 is a block diagram illustrating a system including a non-volatile memory device, according to exemplary embodiments.

### DESCRIPTION OF THE EMBODIMENTS

Various embodiments of the inventive concept will now be described more fully with reference to the accompanying drawings, in which illustrative embodiments are shown. The inventive concept, however, may be embodied in various different forms, and should not be construed as being limited only to the illustrated embodiments. Rather, these embodiments are provided as examples, to convey the inventive concept to one skilled in the art. Accordingly, known processes, elements, and techniques are not described with respect to some of the embodiments. Throughout the drawings and written description, like reference numerals will be used to refer to like or similar elements.

It will be understood that, although the terms first, second, etc., may be used to describe various elements, these elements should not be limited by these terms. These terms are intended merely to distinguish one element from another. For example, a first element could be termed a second element, and similarly, a second element could be termed a first element, without departing from the scope of the inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the inventive concept. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which the inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It should also be noted that in some alternative implementations, the functions/acts noted may occur out of the order indicated in the figures. For example, two figures shown in succession may in fact be executed substantially concurrently or may sometimes be executed in the reverse or alternative order, depending on the functionality/acts involved.

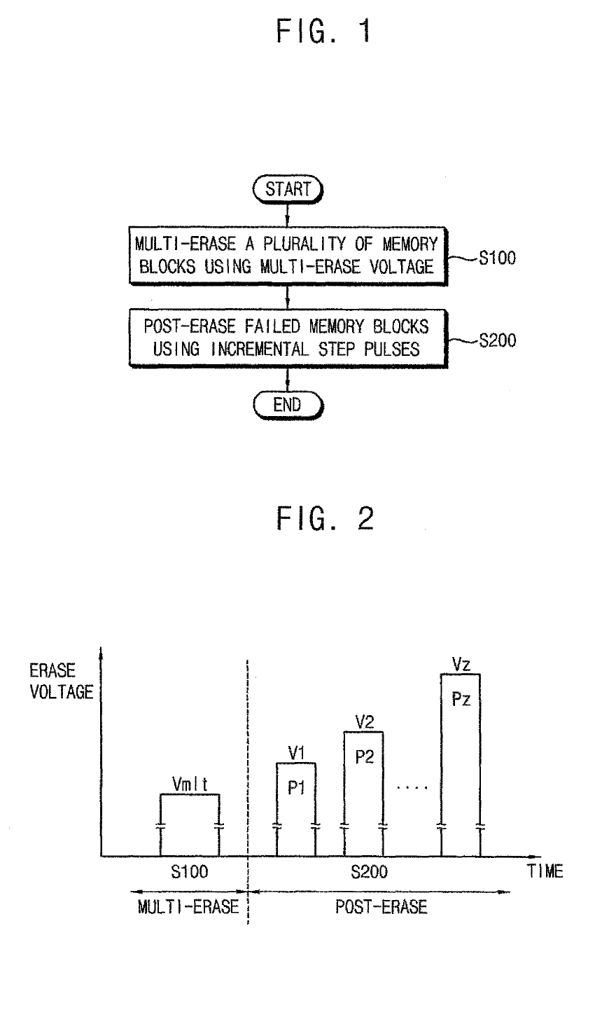

FIG. 1 is a flow chart illustrating a method for performing an erase operation in a non-volatile memory device, according to exemplary embodiments.

Referring to FIG. 1, the method of performing the erase operation in the non-volatile memory device includes a multi-erase operation (Step S100) and a post-erase operation (Step S200).

In the multi-erase operation (Step S100), multiple memory blocks are simultaneously erased using a multi-erase voltage. In the post-erase operation (Step S200), one or more failed memory blocks of the multi-erased memory blocks are erased using a post-erase voltage having increasing voltage values based on incremental step pulses (ISPs). The memory blocks may be rapidly erased in the multi-erase operation, and then threshold voltage distribution of memory cells may be precisely controlled in the post-erase operation.

FIG. 2 is a diagram illustrating a multi-erase voltage and incrementally increasing post-erase voltages based on ISPs, according to exemplary embodiments.

Referring to FIG. 2, the multi-erase voltage Vmlt, which is determined according to threshold voltage characteristics of the memory cells, is applied to multiple memory blocks at the same time during the multi-erase operation (Step S100). Any failed memory block(s), which is not sufficiently erased by the multi-erase voltage, is further erased during the post-erase operation (Step S200). The post-erase voltage has incrementally increasing values V1, V2, . . . , Vz, indicated in FIG. 2, sequentially applied to the failed memory block based on the incrementally increasing ISPs P1, P2, . . . , Pz, respectively.

The number of ISPs P1, P2, . . . , Pz and the number of incremental post-erase voltage values V1, V2, . . . , Vz corresponding to voltage levels of the ISPs P1, P2, . . . , Pz may be adjusted according to characteristics of the memory cells associated with the threshold voltage distribution. For example, as illustrated in FIG. 2, the post-erase voltage V1 corresponding to a start pulse P1 may be higher than the multi-erase voltage Vmlt. An erase verify operation for determining whether each memory block is failed or passed is performed using respective erase verify voltages after applying the multi-erase voltage and after applying each of the incremental post-erase voltages V1, V2, . . . , Vz.

A failed memory block may ultimately be determined to be defective if the memory block remains failed after applying the maximum post-erase voltage Vz corresponding to a voltage level of a last pulse Pz of the ISPs P1, P2, . . . , Pz.

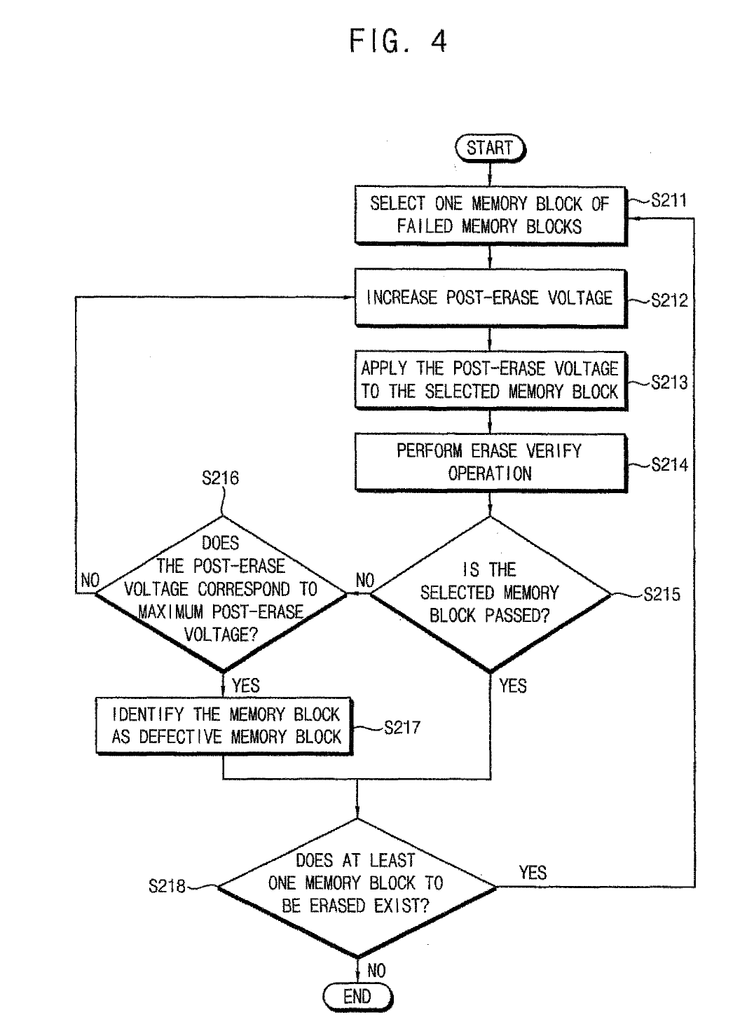

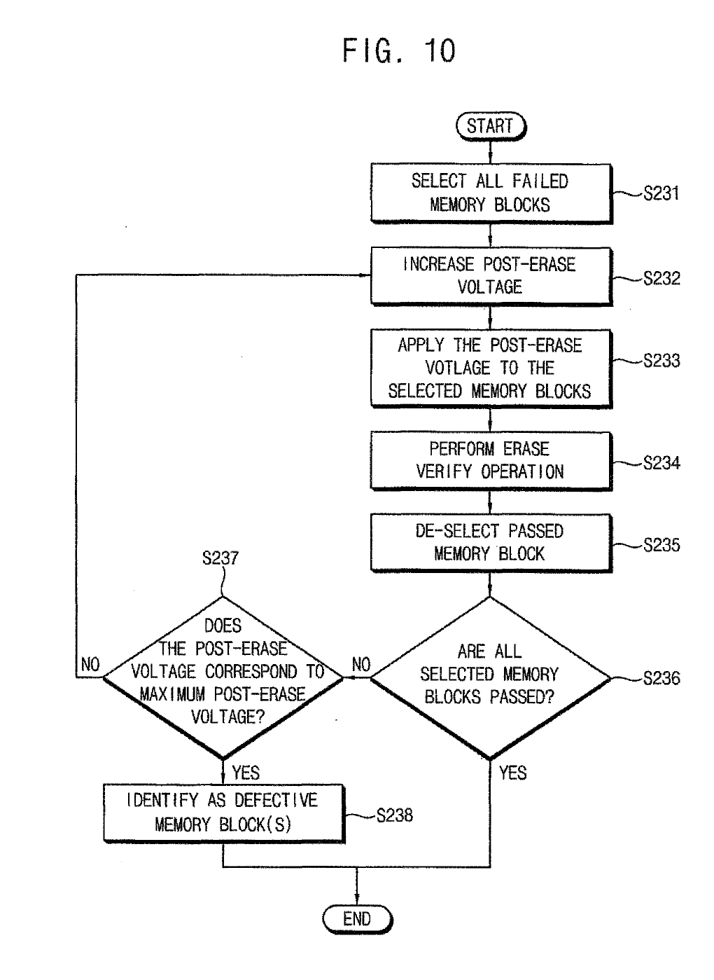

As further described below, the post-erase operation (Step S200) based on the ISPs may be performed with respect to one memory block at a time, e.g., as illustrated in FIG. 4, or may be performed with respect to all of the memory blocks that are determined to be failed memory blocks during the post-erasing operation, e.g., as illustrated in FIG. 10.

As such, the multiple memory blocks are erased at the same time during the multi-erase operation, and then any failed memory blocks are erased based on the ISPs during the post-erase operation. Therefore, the overall erase time is reduced by simultaneously erasing the multiple memory blocks in the multi-erasing operation, and an over-erase problem causing degradations of the memory cells is prevented by applying appropriate voltages according to characteristics of the memory cells in the post-erasing operation. A wide read margin may be achieved by adjusting the threshold voltage distribution of the erased memory cells.

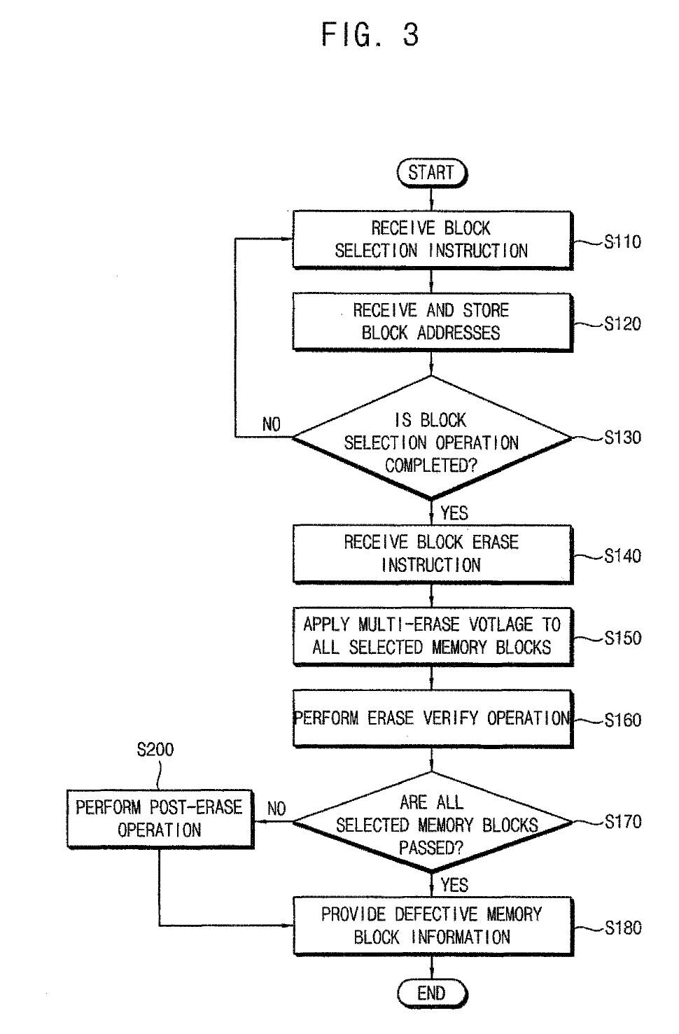

FIG. 3 is a flow chart illustrating an example of a multi-erase operation, according to exemplary embodiments.

In FIG. 3, the multi-erase operation (Step S100) may be performed based on instructions and addresses of the memory blocks associated with the erase operations, which are received from an external memory control device. Examples of the post-erase operation (Step S200) are described below with reference to FIGS. 4 and 10.

Referring to FIG. 3, the non-volatile memory device receives block selection instructions (Step S110). The non-volatile memory device also receives addresses of the memory blocks to be erased, and stores the received addresses (Step S120). In an embodiment, until all of the memory blocks required to be erased are selected, the addresses of the memory blocks required to be erased are repeatedly received and stored. When all memory blocks to be erased are selected (Step S130: YES), a block erase instruction is received (Step S140). In response to the block erase instruction, the multi-erase voltage Vmlt is simultaneously applied to all of the selected memory blocks (Step S150).

For example, the non-volatile memory device may perform the multi-erase operation of FIG. 3 using a latch circuit in a block decoder, typically included in the non-volatile memory device. In this case, the non-volatile memory device receives the block selection instructions and the addresses from the external memory control circuit, and stores erase information in the latch circuit based on the received address of the memory block. The non-volatile memory device may repeatedly receive the addresses until all memory blocks to be erased are selected. After erase information of the memory blocks to be erased is stored in the respective block decoders, the multi-erase voltage is applied to the selected memory blocks at the same time.

The non-volatile memory device verifies whether each memory block has failed or passed with respect to all of the selected memory blocks to be erased (Step S160), and determines whether all of the selected memory blocks have passed (Step S170). When every memory block has passed (Step S170: YES), the non-volatile memory device provides information regarding defective memory blocks (Step S180). In a case where all selected memory blocks have passed after the multi-erase operation, the information regarding defective memory blocks indicates that every memory block is non-defective. The information regarding defective memory blocks may be provided, for example, to the external memory control device. When at least one of the selected memory cells does not pass (Step S170: NO), the post-erase operation is performed (Step S200), and the non-volatile memory device provides the corresponding information regarding defective memory blocks (Step S180).

In FIG. 3, the non-volatile memory device receives the instructions and addresses of the memory blocks associated with the erase operations from the external memory control device to perform the multi-erase operation (Step S100). According to various embodiments, the non-volatile memory device may select the memory blocks to be erased during the multi-erase operation (Step S100) in various ways. For example, when all of the memory blocks included in the non-volatile memory device are required to be erased, the non-volatile memory device may receive an entire-erase instruction or a format instruction from the external memory control device, and sequentially select a predetermined number of memory blocks by using a block address counter, for example, to perform the multi-erase operation (Step S100) and the post-erase operation (Step S200). The block selection instruction may be a single block selection instruction accompanying a single address for selecting one memory block as illustrated in FIG. 3. Alternatively, the block selection instruction may be a multi-block selection instruction accompanying multiple addresses of memory blocks required to be erased, which are sequentially received after the multi-block selection instruction.

The erase verify operation (Step S160) may be performed with respect to all selected memory blocks, and then the post-erase operation (Step S200) may be performed with respect to the failed memory blocks as illustrated in FIG. 3. Alternatively, the erase verify operation (Step S160) may be performed with respect to one memory block of the selected memory blocks, and then the post-erase operation (Step S200) may be performed when the memory block fails. In other words, the erase verify operation (Step S160) and the post-erase operation (Step S200), when needed, may be performed sequentially with respect to each memory block for each of the multi-erased memory blocks.

In various embodiments, the fail information obtained after the multi-erase operation (Step S100) with respect to the memory blocks may be provided to the external memory control device. In this case, the post-erase operation (Step S200) may be performed based on instructions for the post-erase operation and addresses of the memory blocks, which are received from the external memory control device. When the non-volatile memory device receives instructions and addresses of the memory blocks for the post-erase operation from the external memory device, the method according to various embodiments of the inventive concept may be performed without significantly changing the structure of conventional non-volatile memory devices.

In other embodiments, the fail information of the memory blocks after the multi-erase operation (Step S100) may be stored in the non-volatile memory device, and the post-erase operation (Step S200) may be performed based on the stored fail information. When the post-erase operation (Step S200) is performed based on the internally stored fail information, an erase control circuit included in the non-volatile memory device may generate an internal instruction and timing control signals to perform the post-erase operation. In this case, because the additional time for communicating control signals with the external device is not required, the erase time may be further reduced.

FIG. 4 is a flow chart illustrating a post-erase operation, according to exemplary embodiments.

FIG. 4 illustrates an example of the post-erase operation using ISPs, in which the failed memory blocks from the multi-erase operation are further erased, one at a time.

Referring to FIG. 4, one memory block of the failed memory blocks identified during the multi-erase operation (Step S100) is selected (Step S211). The post-erase voltage is increased based on the ISPs P1, P2, . . . , Pz (Step S212), as illustrated in FIG. 2, and the post-erase voltage is applied to the selected memory block (Step S213). At first, the post-erase voltage is increased from the multi-erase voltage Writ to the post-erase voltage V1 corresponding to ISP P1. The selected memory block is verified (Step S214) to determine whether the selected memory block has been correctly erased (passed or failed) using the post-erase voltage. When it is determined that the selected memory block is correctly erased (Step S215: YES), the selected memory block is passed, and when it is determined that the selected memory block has not been correctly erased (Step S215: NO), the selected memory block is failed.

When the selected memory block fails, it is determined whether the post-erase voltage is at its maximum value, corresponding to the maximum post-erase voltage Vz (Step S216). When the post-erase voltage is not at its maximum value (Step S216: NO), the post-erase voltage is incrementally increased (Step S212), and the process is repeated (Steps S213-S216). That is, the selected memory block is repeatedly erased and verified using sequentially increasing post-erase voltage values based on corresponding ISPs until the post-erase voltage is the maximum post-erase voltage Vz (Step S216: YES) corresponding to a voltage level of the last pulse Pz of the ISPs or the selected memory block passes. When the selected memory block is identified as a failed memory block after the post-erase operation is performed using the maximum post-erase voltage Vz, the selected memory block is determined to be defective (Step S217).

As stated above, when the selected memory block is correctly erased within the maximum post-erase voltage Vz based on the ISPs P1, P2, . . . , Pz, the selected memory block is passed (Step S215: YES). When another memory block required to be erased after the multi-erase operation (Step S100) exists (Step S218: YES), the post-erase operation based on ISPs P1, P2, . . . , Pz is repeated with respect to the next memory block (Steps S211 to S217) until all failed memory blocks have been addressed (Step S218: NO).

As illustrated in FIG. 4, one memory block of the failed memory blocks after the multi-erase operation (Step S100) is selected, and the selected memory block is erased by applying an incrementally increasing post-erase voltage based on the ISPs. The post-erase operation (Step S200) may be performed with respect to all of the failed memory blocks after the multi-erase operation, by sequentially repeating selection and erasing of selected memory blocks.

Hereinafter, an example of the method according to embodiments of the inventive concept will be described referring to structures of the non-volatile memory devices.

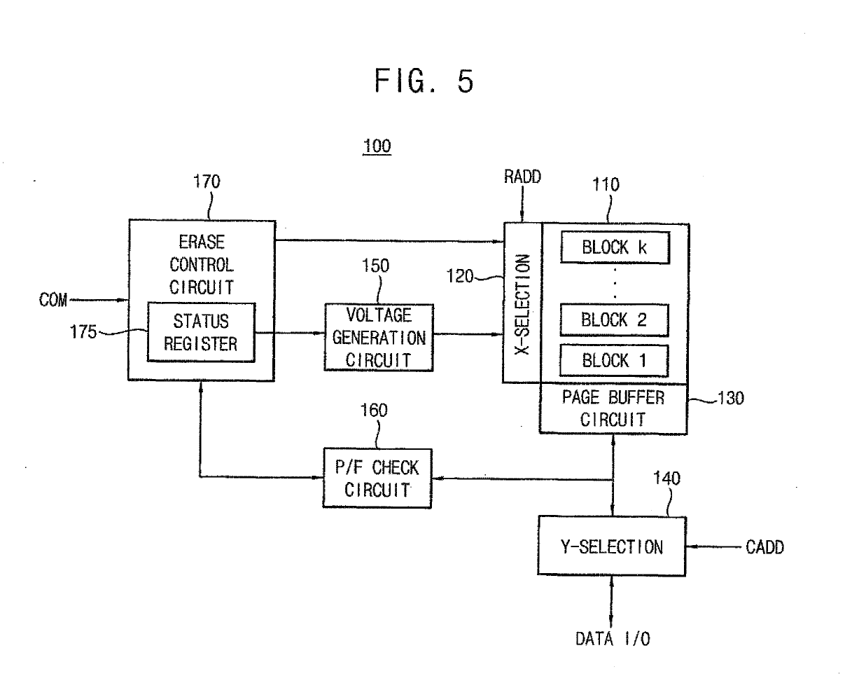

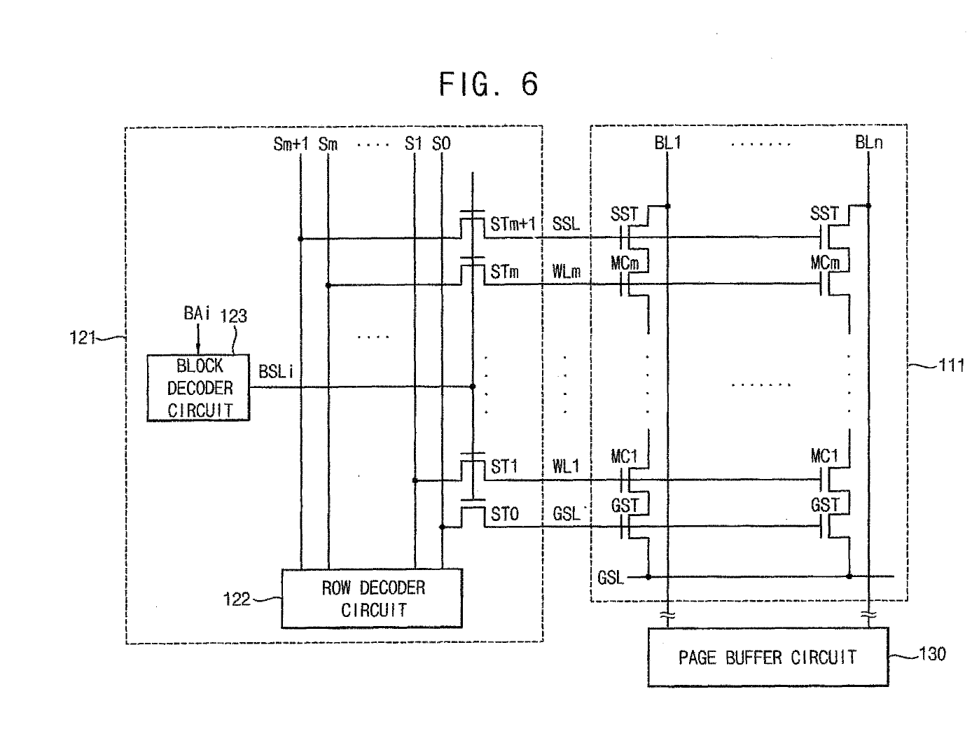

FIG. 5 is a block diagram illustrating a non-volatile memory device, and FIG. 6 illustrates an example configuration for selecting memory blocks of the non-volatile memory device of FIG. 5, according to exemplary embodiments.

The non-volatile memory device 100 of FIG. 5 may correspond to a NAND flash memory device, a NOR flash memory device, or other type of non-volatile memory device which performs erase operations in memory block or sector units.

Referring to FIG. 5, the non-volatile memory device 100 includes memory cell array 110 for storing data. The memory cell array 110 includes multiple memory blocks BLOCK1 to BLOCKk. The non-volatile memory device 100 further includes a row selection circuit 120, a page buffer circuit 130, a column selection circuit 140, a voltage generation circuit 150, a pass/fail check circuit 160 and an erase control circuit 170. The non-volatile memory device 100 further includes an address buffer circuit (not shown) for buffering external addresses and outputting row addresses RADD and column addresses CADD, an input/output (I/O) buffer (not shown) connected to the column selection circuit 140, and an instruction register (not shown) for receiving commands from the external memory control device and outputting the received commands COM.

The address buffer circuit is controlled by the erase control circuit 170 and receives the external addresses through I/O pins. A pre-decoder circuit (not shown) included in the row selection circuit 120 decodes the row addresses RADD from the address buffer circuit and provides block address signals.

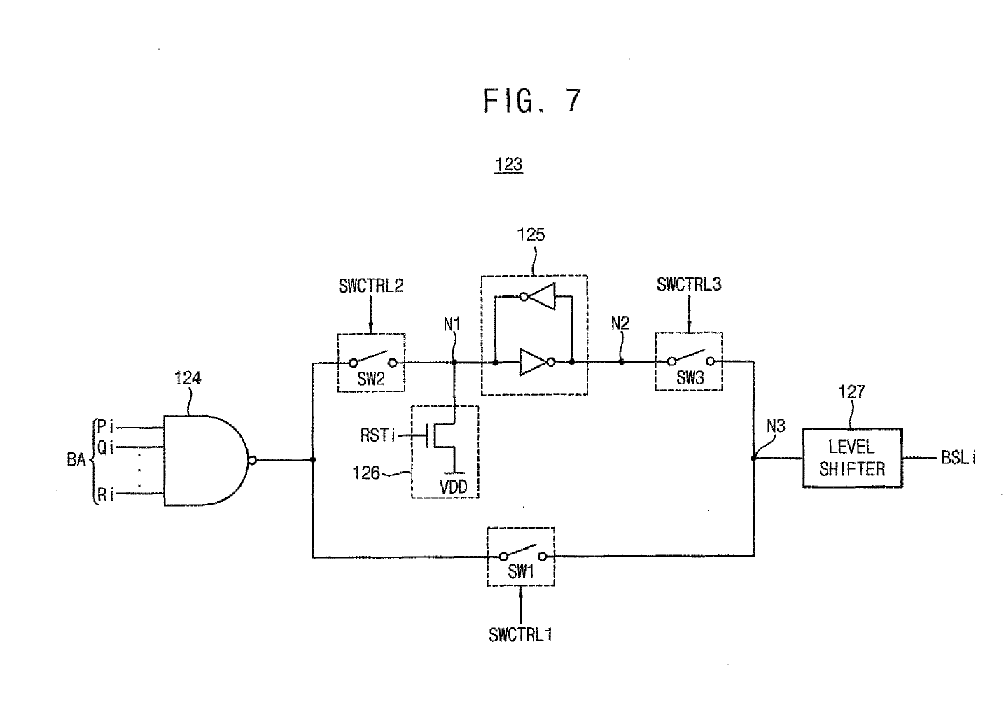

Block decoder circuit 123 (shown in FIG. 6) is controlled by the erase control circuit 170, and selects memory blocks in response to block address information output from the pre-decoder circuit. As will be described with reference to FIG. 7, the block decoder circuit 123 stores the block address information of the memory blocks required to be erased. The row decoder circuit 122 (shown in FIG. 6) applies word line voltages generated by the voltage generation circuit 150 to word lines of the selected memory blocks according to operation modes.

The page buffer circuit 130 includes multiple page buffers respectively connected to corresponding bit lines, and may serve as a sense amplifier and a write driver according to operation modes. For example, the page buffer circuit 130 senses data from the selected memory blocks through the bit lines during a read operation. The page buffer circuit 130 latches data to be written and provides the ground voltage or a power supply voltage to the corresponding bit lines based on the latched data during the program operation. The column selection circuit 140 decodes the column addresses CADD output from the address buffer circuit and selects the page buffers included in the page buffer circuit 130 with respect to each bit. The data read by the page buffer circuit 130 is output to the external device through the column selection circuit 140 and the I/O buffer, and the data to be written is transferred to the page buffer circuit 130 through the column selection circuit 140 and the I/O buffer.

Although not illustrated, the column selection circuit 140 may include an address counter that sequentially increases column addresses to generate successive column addresses. That is, the data to be programmed or read out may be sequentially transferred through the column selection circuit 140.

The pass/fail check circuit 160 receives the data read out by the page buffer circuit 130 during the erase verify operation, and determines whether the data passes or fails. The pass/fail check circuit 160 provides check results to the erase control circuit 170. The voltage generation circuit 150 is controlled by the erase control circuit 170, and generates the word line voltages and the bulk voltages which are required during the multi-erase operation, the post-erase operation, and the erase verify operation. The word line voltages are provided to the word lines pertaining to the selected memory block(s), and the bulk voltage is provided to the bulk of the selected memory block(s) through the row selection circuit 120.

The erase control circuit 170 controls the multi-erase operation (Step S100) and the post-erase operation (Step S200). The erase control circuit 170 generates internal control signals that control input/output timings of addresses, instructions and/or data in response to control signals and instruction signals from the external memory control device. For example, the control or instruction signals may include a command latch enable CLE, an address latch enable ALE, a chip enable/CE, a read enable/RE, a write enable/WE and the like. The internal control signals generated by the erase control circuit 170 may include switch control signals SWCTRL1, SWCTRL2 and SWCTRL3 and a reset signal RSTi, as will be described below with reference to FIG. 7. The erase control circuit 170 controls the block decoder circuit 123 to store sequentially the block addresses of the memory blocks required to be erased through the address buffer circuit and the pre-decoder circuit. The erase control circuit 170 controls the multi-erase operation (Step S100) for simultaneously erasing the memory blocks corresponding to the received block address and controls the post-erase operation (Step S200) with respect to the memory blocks failed in the multi-erase operation. After each erase operation using the multi-erase voltage and the increasing post-erase voltage based on the ISPs is performed, the erase control circuit 170 generates the internal control signals to perform the erase verify operation. The erase verify operation may be performed in response to the erase verification instruction and the block address to be verified received from the external devices. Alternatively, the erase verify operation may be performed based on the fail information stored in the status register 175.

FIG. 6 is a block diagram for describing selection of the memory blocks, according to exemplary embodiments. FIG. 6 illustrates row selection circuit 121, including the block decoder circuit 123 and the row decoder circuit 122, one representative memory block 111 arranged in the memory cell array 110, and the page buffer circuit 130. Even though a memory block of a NAND flash memory device is illustrated in FIG. 6, one of ordinary skill in the art would appreciate that the inventive concept is not limited to NAND flash memory devices.

Referring to FIG. 6, the memory block 111 includes multiple NAND strings, and each NAND string includes a string selection transistor SST, a ground selection transistor GST, and multiple memory cell transistors MC1 to MCm serially connected between the string selection transistor SST and the ground selection transistor GST. Each string is electrically connected to a corresponding bit line of the bit lines BL1 to BLn. The string selection transistor SST is connected to a string selection line SSL, the ground selection transistor GST is connected to a ground selection line GSL, and the memory cell transistors MC1 to MCm are respectively connected to the corresponding word lines WL1 to WLm.

The string selection line SSL, the word lines WL1 to WLm, and the ground selection line GSL are respectively connected to corresponding selection lines S0 to Sm+1 through selection transistors ST0 to STm+1. For example, during the erase operation, the selection lines S0 and Sm+1 connected to the string selection lines SSL and GSL are floated, and the selection lines S1 to Sm connected to the word lines WL1 to WLm are maintained at the ground voltage. The selection transistors ST0 to STm+1 are controlled by the decoded signals from the row decoder 122, and the row decoder 122 controls the selection lines S0 to Sm+1 in response to page address information from the pre-decoder circuit, for example.

The selection transistors ST0 to STm+1 are commonly connected to a block selection line BSLi. The block selection line BSLi is controlled by the block decoder circuit 123. The block decoder circuit 123 is controlled by the erase control circuit 170 and enables/disables the block selection line BSLi in response to decoded block address BAi. The page buffer circuit 130 may include the page buffers respectively connected to the bit lines BL1 to BLn, and each page buffer PB outputs data bits read out during the erase verify operation to the pass/fail check circuit 160 in FIG. 5. The read data bits are used for determining whether the memory block is passed or failed, that is whether the erase operation has been successively performed with respect to the memory blocks.

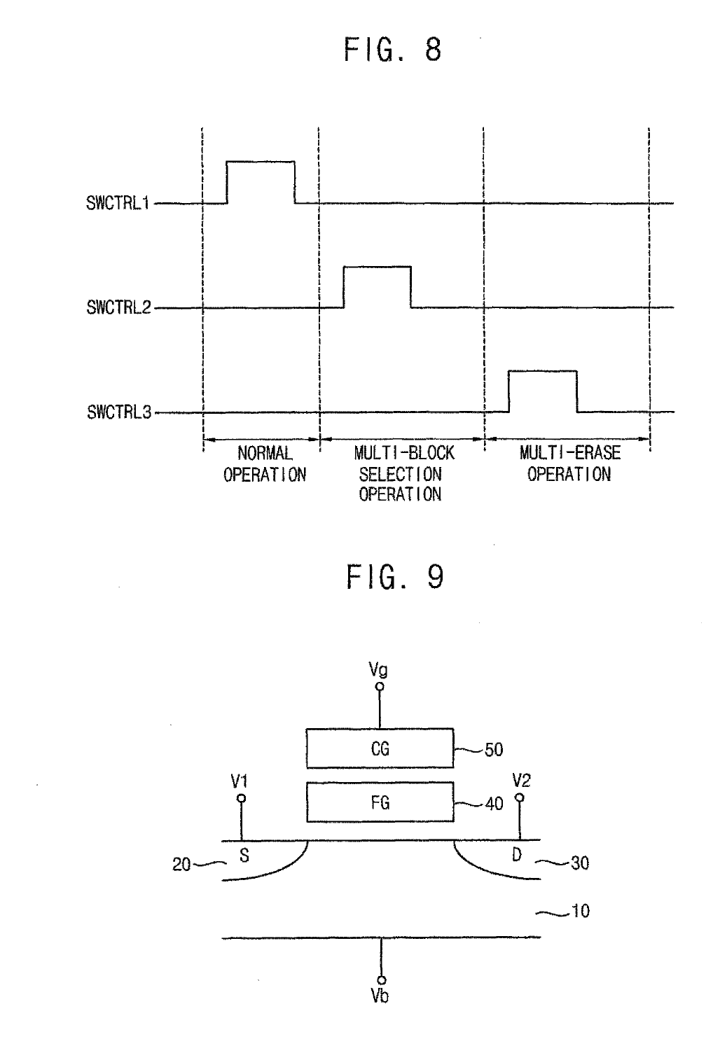

FIG. 7 is a block diagram illustrating an example of the block decoder circuit included in the non-volatile memory device of FIG. 6, and FIG. 8 is a diagram illustrating signals for controlling the block decoder circuit of FIG. 7, according to exemplary embodiments.

The block decoder circuit 123 illustrated in FIG. 7 corresponds to one representative memory block. Other block decoder circuits corresponding to other memory blocks included in the memory cell array 110 may have substantially the same structure as illustrated in FIG. 7. Referring to FIG. 7, the block decoder circuit 123 includes a NAND logic gate 124, a first switch circuit SW1, a second switch circuit SW2, a third switch circuit SW3, a latch circuit 125, a reset circuit 126 and a level shifter 127. The latch circuit 125 includes cross-coupled inverters, for example. The first, second and third switches SW1, SW2 and SW3 may be implemented with various kinds of elements such as transistors, transmission gates, and so on. The level shifter 127 amplifies voltage of an input node N3 to drive the block selection line BSLi. The voltage level of the enabled block selection line BSLi is varied according to the operation modes. For example, the voltage level of the block selection line BSLi may be set to voltages of the selection lines S0 to Sm+1 and transferred to the corresponding lines through the selection transistors ST0 to STm+1 without voltage drop. The voltages transferred to the block selection line BSLi through the level shifter 127 may be provided from the voltage generation circuit 150 in FIG. 5.

The NAND logic gate 124 receives the decoded block address signals Pi, Qi and Ri from the pre-decoder circuit For example, when the memory block including the block decoder circuit 123 is selected, the block address signals Pi, Qi and Ri are enabled to a logic state “high”, and thus, the output signal of the NAND logic gate 124 corresponds to a logic state “low”. The output signal of the NAND logic gate 124 may be selectively transferred to the input node of the level shifter 127 in response to the switch control signals SWCTRL1, SWCTRL2 and SWCTRL3. As mentioned above, the switch control signals SWCTRL1, SWCTRL2 and SWCTRL3 are generated by the erase control circuit 170, and are enabled at predetermined timings controlled by the erase control circuit 170.

The reset circuit 126 initializes storage data of the latch circuit 125 or resets a selection condition of the latch circuit 125 to a de-selection condition. When the erase operation is started, the reset signals RSTi with respect to every block decoder circuit 123 are enabled to the logic state “high”, and then the latch circuit 125 is initialized to the de-selection condition. For example, when an input node N1 of the latch circuit 125 corresponds to the logic state “low”, the latch circuit 125 corresponds to the selection condition. When the input node N1 of the latch circuit 125 corresponds to the logic state to “high”, the latch circuit 125 corresponds to the de-selection condition. When the memory block is passed in the erase verify operation, during the post-erase operation (Step S200), the reset signal RSTi applied to the block decoder circuit of the passed memory block is enabled to de-select the passed memory block. The de-selection of the passed memory block (e.g., Step S235 of FIG. 10) may be performed by enabling the reset signal RSTi to reset the selection condition to the de-selection condition.

Referring to FIG. 8, the first switch control signal SWCTRL1 is enabled during normal operations, such as a read operation, a program operation and a single block erase operation. The second switch control signal SWCTRL2 is enabled to select the memory blocks to be erased, and the second switch circuit SW2 transfers the output signal of the NAND logic gate 124 to the input node N1 of the latch circuit 125 when the second switch control signal SWCTRL2 is enabled and the output signal of the NAND logic gate 124 corresponds to the logic state “low”. The latch circuit 125 included in the block decoder circuit 123 respectively stores the selection/de-selection condition of the memory blocks. The third switch control signal SWCTRL3 is enabled to perform the multi-erase operation (Step S100) after the memory blocks are selected. When the third switch control signal SWCTRL3 is enabled, the block selection line BSLi is enabled according to the selection/de-selection condition stored in the latch circuit 125 to perform the erase operation only on the selected memory blocks.

Referring to FIG. 7 again, when the reset signal RSTi is enabled to the logic state “high”, the latch circuit 125 is initialized to the de-selection condition and the first to third switch control signals SWCTRL1, SWCTRL2 and SWCTRL3 are disabled to the logic state “low”. When the decoded block address signals Pi, Qi and Ri are provided to the NAND logic gate 124 by the pre-decoder circuit based on the addresses of the memory blocks to be erased, the erase control circuit 170 enables the second switch control signal SWCTRL2. When the decoded block address signals Pi, Qi and Ri correspond to the logic state “high” and the second switch control signal SWCTRL2 is enabled, the output signal of the NAND logic gate 124 corresponding the logic state “low” is transferred to the input node Ni of the latch circuit 125 through the second switch circuit SW2, and thus the latch circuit 125 is converted to store the selection condition. Because the third switch control signal SWCTRL3 is disabled, the block selection line BSLi is not driven by the level shifter 127.

As discussed above, the block selection instruction and then the block address are received. The received block address is stored in the latch circuit 125 included in the corresponding block decoder circuit 123 according to the controlling of the erase control circuit 170. Receiving the block address and storing the selection/de-selection condition in the latch circuit 125 are repeated until the block addresses of every memory block to be erased are stored in the corresponding block decoder circuit.

After the decoded block addresses to be erased are stored in the block decoder circuit 123, the erase control circuit 170 enables the third switch control signal SWCTRL3 in response to the block erase instruction. The selection/de-selection condition stored in the latch circuit 125 is transferred to the input node N3 of the level shifter 127 in response to the third switch control signal SWCTRL3. The level shifter 127 enables connected block selection line BSLi in response to the logic state of the input node N3, and thus the block selection line BSLi included in the selected memory blocks are enabled. As such, the selected memory blocks may be simultaneously erased through the multi-erase operation.

FIG. 9 is a cross-sectional view of a non-volatile memory cell, according to exemplary embodiments.

In the non-volatile memory cell, a source region 20 and a drain region 30 are formed in a substrate 10, and a floating gate 40 and a control gate 50 are stacked on the substrate 10 between the source region 20 and the drain region 30. A dielectric layer, such as an oxide-nitride-oxide (ONO) layer, is formed between the control gate 50 and the floating gate 40, and a tunnel oxide layer is formed between the floating gate 40 and the upper substrate 10. Alternatively, the well region may be first formed by doping low-density impurities in the substrate 10, and then the source region 20 and the drain region 30 are formed in the well region. A gate voltage Vg, a source voltage V1, a drain voltage V2 and the bulk voltage Vb are controlled to have predetermined values according to the program/read/erase operations, and various kinds of erase methods may be applicable, according to structures of the memory cells of the non-volatile memory device.

Every two adjacent memory cells included in a NAND flash memory device may share the source and drain regions, and thus may be serially connected with each other to form a NAND string. The NAND string may be connected to the bit line through the selection transistor. For example, in the NAND flash memory device, the bulk voltage corresponding to a positive high voltage, such as about 20V, and the control gate 50 corresponding to the ground voltage may be used to inject electrons from the bulk region to the floating gate 40 through tunneling phenomenon during the erase operation. In this case, the multi-erase voltage Vmlt and each incremental post-erase voltage V1, V2, . . . , Vz correspond to the bulk voltage which is applied to the substrate or the well region.

In a NOR flash memory device, the control gate 50 corresponds to a negative high voltage and the bulk voltage corresponds to the ground voltage or a positive voltage during the erase operation. For reducing an absolute value of the negative voltage applied to the control gate 50, a predetermined positive voltage may be applied to the drain region 30 during the erase operation. The multi-erase voltage Vmlt and each of the incremental post-erase voltages V1, V2, . . . , Vz are applied to the drain regions of the NOR flash memory cells during the erase operation.

FIG. 10 is a flowchart illustrating a post-erase operation, according to exemplary embodiments.

FIG. 10 illustrates the post-erase operation using ISPs with respect to all of the failed memory blocks. The post-erase operation is performed to further erase all of the failed memory blocks, identified as having failed the multi-erase operation.

Referring to FIG. 10, all of the failed memory blocks are selected (Step S231) after the multi-erase operation (Step S100). As illustrated in FIG. 2, the post-erase voltage is increased based on the ISPs P1, P2, . . . , Pz (Step S232), and the increased post-erase voltage is applied to every selected memory block (Step S233). At first, the post-erase voltage is increased from the multi-erase voltage Vmlt to the post-erase voltage V1 corresponding to ISP P1. The erase verify operation is performed on the selected memory blocks (Step S234) to determine whether the selected memory blocks are failed or passed, and the memory blocks determined as passed memory blocks are de-selected. (Step S235). As described with reference to FIG. 7, the de-selecting operation may be performed to convert the stored data of the latch circuit 125 by enabling the reset signal RSTi applied to the block decoder circuit 123 of the passed memory blocks.

Based on the erase verify operation, it is determined whether all of the selected memory blocks are passed (Step S236). When at least one memory block has not passed (Step S236: NO), it is determined whether the post-erase voltage is at its maximum value, corresponding to the maximum post-erase voltage Vz (Step S237). When the post-erase voltage is not at its maximum value (Step S237: NO), the post-erase voltage is incrementally increased (Step S232), and the process is repeated (Steps S233-S236). That is, the de-selecting operations are repeatedly performed on the failed memory blocks by successively increasing the post-erase voltage until the memory blocks pass or the post-erase voltage is the maximum erase voltage Vz corresponding to the voltage level of the last pulse Pz. When the post-erase voltage is the maximum erase voltage Vz (Step S237: YES), the memory to blocks are identified as defective memory blocks (Step S238), and the post-erase operation is terminated. When all of the failed memory blocks are determined to have passed (Step S236: YES), that is, every failed memory block has been successfully erased within the maximum post-erase voltage, the post-erase operation (Step S200) is terminated.

In the example of the post-erase operation illustrated in FIG. 10, all of the failed memory blocks are selected after the multi-erase operation (Step S100). All of the failed memory blocks are simultaneously erased, and then the passed memory blocks are de-selected. The post-erase operation may be performed by repeating the erasure of all failed memory blocks, and de-selection of the passed memory blocks based on the erase verify operation with respect to the incremental post-erase voltages V1, V2, . . . , Vz corresponding to the ISPs P1, P2, . . . , Pz.

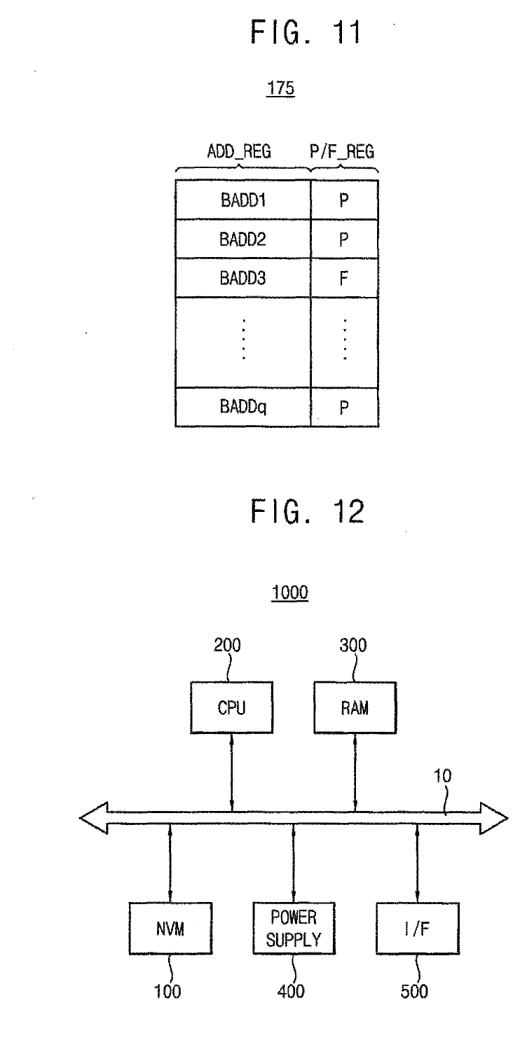

FIG. 11 is a diagram illustrating an example of the status register included in the non-volatile memory device of FIG. 5, according to exemplary embodiments.

As illustrated in FIG. 5, the erase control circuit 170 includes status register 175, which stores information required for controlling erase operations. Referring to FIG. 11, the status register 175 includes an address register ADD_REG storing addresses of multiple memory blocks BADD1 to BADDq selected for the multi-erase operation, and a pass/fail register P/F_REG representing whether each memory block is failed or passed with respect to the memory blocks. In this case, the erase control circuit 170 may perform the post-erase operation based on the stored information in the status register 175 to further reduce the time required for communicating with the external memory control device. For example, the erase control circuit 170 may generate internal block addresses BA, the reset signal RSTi, the switch control signals SWCTRL1, SWCTRL2 and SWCTRL3, and so on, based on the fail information stored in the status register 175 included in the non-volatile memory device to perform the selecting of the failed memory blocks (e.g., Step S231 of FIG. 10) and the de-selecting of the passed memory blocks (e.g., Step S235 of FIG. 10).

FIG. 12 is a block diagram illustrating a system including a non-volatile memory device, according to exemplary embodiments.

Referring to FIG. 12, a system 1000 includes the non-volatile memory device (NVM) 100, a central processing unit (CPU) 200, a random access memory device (RAM) 300, a power supply 400, and an interface 500. The elements are respectively coupled via a bus 10.

As discussed above, the non-volatile memory device 100 includes structures for performing erase operations, including the multi-erase operation (Step S100) and the post-erase operation (Step S200) in the memory blocks. The central processing unit 200 controls overall performance of the system, and may directly control the non-volatile memory device 100. Alternatively, a dedicated memory controller (not shown) included in the non-volatile memory device 100 may control the non-volatile memory device 100. According to various embodiments, the non-volatile memory device 100 and the memory controller may be connected to the system bus 10 through the memory interface, so that the non-volatile memory device 100 and the memory controller may be externally implemented.

RAM 300 may temporality store the data required for performing the erase operations. For example, RAM 300 may receive the block address from the central processing unit 200 or the external device, temporality store the block address and provide the stored block address to the non-volatile memory device 100 through the bus 10.

The power supply 400 provides a power supply voltage VDD to the system 1000. The power supply 400 may be implemented externally from the system 1000. The interface 500 converts or interfaces external signals to be compatible with the system 1000.

The system 1000, according to embodiments of the inventive concept, may be mounted in various packages. Each package may include functional blocks consistent with the system and/or peripheral devices, as well as the types and configurations of flash memory device and memory controller. For example, the package may include a PoP (Package on Package), Ball grid arrays (BGAs), Chip scale packages (CSPs), a Plastic Leaded Chip Carrier (PLCC), a Plastic Dual In-Line Package (PDIP), a Die in Waffle Pack, a Die in Wafer Form, a Chip On Board (COB), a Ceramic Dual In-Line Package (CERDIP), a Plastic Metric Quad Flat Pack (MQFP), a Thin Quad Flatpack (TQFP), a Small Outline (SOIC), a Shrink Small Outline Package (SSOP), a Thin Small Outline (TSOP), a Thin Quad Flatpack (TQFP), a System In Package (SIP), a Multi Chip Package (MCP), a Wafer-level Fabricated Package (WFP), a Wafer-Level Processed Stack Package (WSP), and the like.

For example, the system 1000, including the non-volatile memory device 100 and the memory controller for performing the erase operation according to various embodiments, may be a memory card. The memory card may include the interface circuit 500 to communicate with the external device, such as a host device, through at least one of a universal serial bus (USB), a multimedia card (MMC), a Peripheral Component Interconnect-Express (PCI-E), a Serial Advanced Technology Attachment (SATA), a Parallel Advanced Technology Attachment (PATA), a small computer system interface (SCSI), an enhanced small device interface (ESDI), an integrated drive electronics (IDE), and the like.

Also, for example, the system 1000, including the non-volatile memory device 100 and the memory controller, may be a mobile device, such as a cellular phone, a personal data assistant (PDA), a digital camera, a portable game console, and an MP3 player, and the like. In various embodiments, the flash memory device 100 may be used for code storage, as well as data storage.

Further, the system 1000 for performing the erase operations, according to embodiments of the inventive concept, may also apply to home applications, such as a high definition television (HDTV), a digital video disk or a digital versatile disk (DVD), a router, a global positioning system (GPS), and the like.

Likewise, the system 1000 including the non-volatile memory device 100 and the memory controller may be a computing system. When the system 1000 is a computing system, the system 1000 may further include a microprocessor, a user interface and modem, such as a baseband chipset, all of which may be electrically connected to the bus 10. The non-volatile memory device 100 may store N-bit data (N being an integer that is at least one) through the memory controller. The N-bit data may be processed by the microprocessor. When the computing system according to various embodiments is a mobile device, discussed above, a battery providing operation voltage of the computing system may also be included. The computing system may further include an application chipset, a camera image processor (CIS), a mobile dynamic random access memory (DRAM), and the like, depending on various desired capabilities and applications.

The system 1000, according to various embodiments, may be a solid state drive/disk (SSD), using the non-volatile memory device storing the data, for example.

The non-volatile memory device is able to retain stored data even when a supply voltage is not provided. Therefore, as would be appreciated by one of ordinary skill in the art, the non-volatile memory device 100 configured to perform the erasing operations according to various embodiments may be applicable to various other kinds of systems and devices incorporating the non-volatile memory device 100.

The method of erasing according to embodiments of the inventive concept may be applicable to the non-volatile memory device and various kinds of systems and devices which include the non-volatile memory device. Thus, for example, degradation of the memory cells may be reduced or prevented. Also, erase time may be reduced, e.g., by simultaneously erasing the memory blocks in the multi-erase operation and/or by reducing communications with a controller. An over-erase problem may be prevented by sequentially increasing the post-erase voltage applied to the memory blocks that remain failed after the multi-erase operation.

While the present inventive concept has been described with reference to exemplary embodiments, it will be apparent to those skilled in the art that various changes and modifications may be made without departing from the spirit and scope of the present teachings. Therefore, it should be understood that the above embodiments are not limiting, but illustrative.

What is claimed is:

1. A method of performing an erase operation in a non-volatile memory device, the method comprising:
multi-erasing a plurality of memory blocks at the same time using a multi-erase voltage; and
post-erasing one or more failed memory blocks of the multi-erased memory blocks using a post-erase voltage having sequentially increasing voltage values based on incremental step pulses (ISPs).

2. The method of claim 1, wherein a minimum post-erase voltage value corresponding to a start pulse of the ISP is higher than the multi-erase voltage.

3. The method of claim 1, further comprising:
identifying a memory block as a defective memory block when the memory block remains failed after erasing the memory block using a maximum post-erase voltage value corresponding to a last pulse of the ISPs.

4. The method of claim 1, further comprising:
providing fail information of the failed memory blocks to an external memory control device; and
receiving instructions and block addresses from the memory control device, the post-erasing being performed based on the received instructions and block addresses.

5. The method of claim 1, further comprising:
storing fail information regarding the failed memory blocks after the multi-erasing within the non-volatile memory device, the post-erasing being performed based on the stored fail information.

6. The method of claim 1, wherein the post-erasing comprises:
selecting one memory block of the failed memory blocks after the multi-erasing;
erasing the selected memory block using the post-erase voltage having sequentially increasing voltage values based on the ISPs; and
repeating the selecting one memory block and the erasing the selected memory block with respect to each of the failed memory blocks.

7. The method of claim 1, wherein the post-erasing comprises:
selecting all of the failed memory blocks after the multi-erasing;
simultaneously erasing the selected failed memory blocks using the post-erase voltage;
performing an erase verification of all of the failed memory blocks and identifying a passed memory block based on the erase verification;
de-selecting the passed memory block from the selected failed memory blocks; and
repeating the simultaneously erasing the selected failed memory blocks and the de-selecting a passed memory block using the post-erase voltages having sequentially increasing voltage values based on the ISPs.

8. The method of claim 7, wherein the selecting all of the failed memory blocks and the de-selecting the passed memory block are performed based on fail information stored in a status register included in the non-volatile memory device.

9. The method of claim 1, wherein the multi-erasing comprises:
receiving a block selection instruction and an address of a memory block to be erased from an external memory control device;
storing erase information in a block decoder included in the non-volatile memory device based on the received address;
repeating the receiving and the storing until all of the memory blocks to be erased are selected; and
applying the multi-erase voltage to the plurality of memory blocks at the same time.

10. The method of claim 1, wherein the multi-erase voltage and the post-erase voltages based on the ISPs correspond to a bulk voltage applied to a substrate or a well region, in which flash memory cells are formed.

11. A method of performing an erase operation in a non-volatile memory device, the method comprising:
performing a multi-erase operation comprising simultaneously erasing a plurality of memory blocks using a multi-erase voltage;
performing an erase verify operation on the plurality of memory blocks to identify at least one failed memory block that is not sufficiently erased following the multi-erase operation; and
performing a post-erase operation on the at least one failed memory block, the post-erase operation comprising erasing the at least one failed memory block using a post-erase voltage, verifying whether the at least one failed memory block is sufficiently erased, and when the at least one failed memory block is not sufficiently erased, incrementally increasing the post-erase voltage based on an incremental step pulse (ISP) and again erasing the at least one failed memory block.
